(19) United States
(12) Patent Application Publication
(10) Pub. No.: US 2019/0237017 A1
(43) Pub. Date: Aug. 1, 2019

(54) PIXEL DRIVING CIRCUIT, DRIVING METHOD, DISPLAY PANEL, AND DISPLAY DEVICE

(71) Applicant: SHANGHAI TIANMA AM-OLED CO., LTD., Shanghai (CN)

(72) Inventors: Dongxu XIANG, Shanghai (CN); Renyuan ZHU, Shanghai (CN); Yue LI, Shanghai (CN); Yana GAO, Shanghai (CN); Zhonglan CAI, Shanghai (CN)

(21) Appl. No.: 15/961,025

(22) Filed: Apr. 24, 2018

(30) Foreign Application Priority Data
Jan. 26, 2018 (CN) 201810076398.5

(51) Int. Cl. G09G 3/3241

(52) U.S. Cl. CPC G09G 3/3241; H01L 27/3262; G09G 2300/0819; G09G 2320/0214

(57) ABSTRACT

A pixel driving circuit, a driving method, a display panel, and a display device are provided. The pixel driving circuit comprises: data writing module, in response to a scan signal transmitting a data signal; mirror driving module, receiving the data signal and generating a driving current, and including a first transistor and a second transistor; and a light-emitting element, in response to the driving current emitting lights. A gate electrode of the first transistor and a gate electrode of the second transistor are both electrically connected to a first joint. A first electrode of the first transistor is electrically connected to a first electrode of the second transistor. A threshold voltage of the first transistor is equal to a threshold voltage of the second transistor. An aspect ratio of the first transistor is A and an aspect ratio of the second transistor is B, and A<B≤20A.

### CROSS-REFERENCES TO RELATED APPLICATIONS

This application claims priority of Chinese Patent Application No. 201810076398.5, filed on Jan. 26, 2018, the entire contents of which are hereby incorporated by reference.

### FIELD OF THE INVENTION

The present disclosure generally relates to the field of display technology and, more particularly, relates to a pixel driving circuit, a driving method, a display panel, and a display device thereof.

### BACKGROUND

The display panels provided by existing technologies include a plurality of pixels, the pixels include a pixel driving circuit, and the pixel driving circuit is provided for controlling the plurality of pixels to emit lights.

The pixel driving circuit can be classified, according to the operating principle, into a current-programmed-type pixel driving circuit and a voltage-programmed-type pixel driving circuit. In the current-programmed-type pixel driving circuit, the problem of charging duration being too long may occur, and the phenomenon of an electric leakage current can also be present in the wiring for transmitting electric current signals, leading to a larger difference between the electric current finally written into the pixel driving circuit and the electric current initially programmed, which affects the display effect of the plurality of pixels and lowers the display quality of a display panel.

The disclosed display panel, driving method, and display device thereof are directed to solve one or more problems set forth above and other problems.

### BRIEF SUMMARY OF THE DISCLOSURE

One aspect of the present disclosure provides a pixel driving circuit. The pixel driving circuit comprises: a data writing module, in response to a scan signal transmitting a data signal; a mirror driving module, receiving the data signal and generating a driving current, and including a first transistor and a second transistor; and a light-emitting element, in response to the driving current emitting lights. A gate electrode of the first transistor and a gate electrode of the second transistor are both electrically connected to a first joint. A first electrode of the first transistor is electrically connected to a first electrode of the second transistor. A threshold voltage of the first transistor is equal to a threshold voltage of the second transistor. An aspect ratio of the first transistor is A and an aspect ratio of the second transistor is B, and A<B≤20A.

Another aspect of the present disclosure provides a display panel. The display panel comprises: a non-display area; a display area, including a plurality of pixels; and a pixel driving circuit for driving the plurality of pixels. The pixel driving circuit comprises: a data writing module, in response to a scan signal, for transmitting a data signal; a mirror driving module for receiving the data signal and generating a driving current, including a first transistor and a second transistor; and a light-emitting element, in response to the driving current for emitting lights. A gate electrode of the first transistor and a gate electrode of the second transistor are both electrically connected to a first joint. A first electrode of the first transistor is electrically connected to a first electrode of the second transistor. A threshold voltage of the first transistor is equal to a threshold voltage of the second transistor. An aspect ratio of the first transistor is A and an aspect ratio of the second transistor is B, and A<B≤20A.

Another aspect of the present disclosure provides a driving method of a pixel driving circuit. The pixel driving circuit includes a data writing module, a mirror driving module, and a light-emitting element. The mirror driving module includes a first transistor and a second transistor. A gate electrode of the first transistor and a gate electrode of the second transistor are both electrically connected to a first joint. A first electrode of the first transistor is electrically connected to a first electrode of the second transistor. A threshold voltage of the first transistor is equal to a threshold voltage of the second transistor. An aspect ratio of the first transistor is A and an aspect ratio of the second transistor is B, and A<B. The driving method comprises: providing a data writing stage and a light-emitting stage; in the data writing stage, inputting a scan signal into the data writing module, in which the data writing module in response to the scan signal transmits a data signal to the first joint; and in the light-emitting stage, receiving, by the mirror driving module, the data signal and generating a driving current to drive the light-emitting element for emitting lights.

Other aspects of the present disclosure can be understood by those skilled in the art in light of the description, the claims, and the drawings of the present disclosure.

### BRIEF DESCRIPTION OF THE DRAWINGS

The following drawings are merely examples for illustrative purposes according to various disclosed embodiments and are not intended to limit the scope of the present disclosure.

FIG. 1 illustrates a schematic structural diagram of an exemplary pixel driving circuit consistent with disclosed embodiments;

FIG. 2 illustrates another schematic structural diagram of an exemplary pixel driving circuit consistent with disclosed embodiments;

FIG. 3 illustrates another schematic structural diagram of an exemplary pixel driving circuit consistent with disclosed embodiments;

FIG. 4 illustrates another schematic structural diagram of an exemplary pixel driving circuit consistent with disclosed embodiments;

FIG. 5 illustrates another schematic structural diagram of an exemplary pixel driving circuit consistent with disclosed embodiments;

FIG. 6 illustrates an operation timing diagram of the exemplary pixel driving circuit of FIG. 5 consistent with disclosed embodiments;

FIG. 7 illustrates another schematic structural diagram of an exemplary pixel driving circuit consistent with disclosed embodiments;

FIG. 8 illustrates another schematic structural diagram of an exemplary pixel driving circuit consistent with disclosed embodiments;

FIG. 9 illustrates a structural diagram of an exemplary display panel consistent with disclosed embodiments; and

FIG. 10 illustrates a structural diagram of an exemplary display device consistent with disclosed embodiments.

### DETAILED DESCRIPTION

Various exemplary embodiments of the present disclosure will now be described in detail with reference to the accompanying drawings. It should be noted that, unless it is stated otherwise, the relative arrangement of the components and steps, the numerical expressions and values set forth in these embodiments are for examples only and do not limit the scope of the present disclosure.

The following description of at least one embodiment is merely illustrative in nature and is by no means intended to limit the disclosure and its application or use.

Techniques, methods, and devices known to those skilled in the relevant art may not be discussed in detail, but the techniques, methods, and devices should be considered as part of the description where appropriate.

In examples presented and discussed herein, any specific value should be interpreted as illustrative only and not as a limitation. Therefore, other examples of the exemplary embodiments may have different values.

It should be noted that similar reference numerals and letters refer to similar items in the accompanying drawings. Hence, once an item is defined in one figure, it doesn't need to be further discussed in subsequent figures.

The present disclosure provides a pixel driving circuit, including a data writing module 10, a mirror driving module 20, and a light-emitting element D.

The data writing module 10 may transmit a data signal IDATA in response to a scan signal SCAN.

The mirror driving module 20 may receive the data signal IDATA and generate a driving current.

The mirror driving module 20 may include a first transistor M1 and a second transistor M2. A gate electrode of the first transistor M1 and a gate electrode of the second transistor M2 may be both electrically connected to a first joint N1. A first electrode of the first transistor M1 may be electrically connected to a first electrode of the second transistor M2.

A threshold voltage of the first transistor M1 may be equal to a threshold voltage of the second transistor M2. An aspect ratio (i.e., width-to-length ratio) of the first transistor M1 may be A, an aspect ratio of the second transistor M2 may be B, and A<B≤20A.

The light-emitting element D may emit lights in response to the driving current.

The pixel driving circuit disclosed by this embodiment is of a current-programmed type. The data signal IDATA may be written into the pixel driving circuit in the form of an electric current signal.

In the mirror driving module 20, the gate electrode of the first transistor M1 may be electrically connected to the gate electrode of the second transistor M2, and the first electrode of the first transistor M1 may be electrically connected to the first electrode of the second transistor M2, such that the first transistor and the second transistor form an electric current mirror, which is characterized as that an output current is a proportional “copy” of an input current.

In particular, it is known that when a metal-oxide-semiconductor field effect transistor (MOSFET) operates in a saturation region, the electric current is expressed by the following equation:

I=0.5k*(W/L)*(Vgs−Vth)². (1)
where k is a constant, W/L is the aspect ratio of the transistor, V_{gs}=V_{g}−Vₛ, V_{g} is the gate voltage of the transistor, Vₛ is the first-electrode voltage of the transistor, i.e., V_{gs} is the gate-source voltage of the transistor, and Vₜₕ is the threshold voltage of the transistor.

In this embodiment, an input current Iₑ may be fed to the mirror driving module 20, the mirror driving module 20 can generate an output current Iₒ, in which the data signal IDATA is the input current Iₑ.

According to the operating principle of the electric current mirror, the input current Iₑ is the electric current of the second transistor M2 operating in the saturation region, while the output current Io is the electric current of the first transistor M1 operating in the saturation region.

In accordance with the equation (1), the input current Iₑ is given by Iₑ=0.5k*(W₂/L₂)*(Vgs₂−Vth₂) □, where W₂/L₂ is the aspect ratio of the second transistor M2, V_{gs2} is the gate-source voltage of the second transistor M2, and Vₜₕ₂ is the threshold voltage of the second transistor M2. The output current Iₒ is expressed as Iₒ=0.5k*(W₁/L₁)*(Vgs₁−Vth₁) □, where W₁/L₁ is the aspect ratio of the first transistor M1, V_{gs1} is the gate-source voltage of the first transistor M1, and Vₜₕ₁ is the threshold voltage of the first transistor M1.

Then, the ratio of the output current Iₒ to the input current Iₑ is expressed by the following equation (2):

$$\frac{Io}{Ie} = \frac{0.5 k * ( W 1 / L 1 ) * {( Vgs 1 - Vth 1 )}^{2}}{0.5 k * ( W 2 / L 2 ) * {( Vgs 2 - Vth 2 )}^{2 }} \qquad ( 2 )$$

Since k is a constant, after eliminating k, equation (2) simplifies to:

$$\frac{Io}{Ie} = \frac{( W 1 / L 1 ) * {( Vgs 1 - Vth 1 )}^{2}}{( W 2 / L 2 ) * {( Vgs 2 - Vth 2 )}^{2 }} \qquad ( 3 )$$

In this embodiment, since the gate electrode of the first transistor M1 is electrically connected to the gate electrode of the second transistor M2, and the first electrode of the first transistor M1 is electrically connected to the first electrode of the second transistor M2, the relationship of V_{gs1}=V_{gs2} holds. Moreover, in this embodiment, the threshold voltage of the first transistor M1 may be set to be equal to the threshold voltage of the second transistor M2, i.e., Vₜₕ₁=Vₜₕ₂. As a result, the ratio of the output current Iₒ to the input current Iₑ becomes:

$$\frac{Io}{Ie} = \frac{( W 1 / L 1 )}{( W 2 / L 2 )} \qquad ( 4 )$$

It can be understood that the threshold voltage of the first transistor M1 may not be equal to the threshold voltage of the second transistor M2. If the threshold voltage of the first transistor M1 is close to the threshold voltage of the second transistor M2, the following r relationship can be obtained:

$$\frac{Io}{Ie} \approx \frac{( W 1 / L 1 )}{( W 2 / L 2 )} \qquad ( 4 ’ )$$

In the pixel driving circuit consistent with the present disclosure, the aspect ratio of the first transistor M1 may be set as A, i.e., W₁/L₁=A, and the aspect ratio of the second transistor M2 may be set as B, i.e., W₂/L₂=B. Thus, the ratio of the output current Iₒ to the input current Iₑ yields:

$$\frac{Io}{Ie} = \frac{A}{B} \qquad ( 5 )$$

According to equation (5), the relationship of

$${I}_{0} = \frac{A}{B} * {I}_{e}$$

can be obtained. In this embodiment, the condition A<B≤20A can be set, i.e.,

$$\frac{Ie}{20} \leq {I}_{o} < {I}_{e} .$$

That is, in the pixel driving circuit consistent with the present disclosure, the output current of the mirror driving module 20 is smaller than the input current of the mirror driving module 20, and

$$\frac{Ie}{20} \leq {I}_{o} < {I}_{e} .$$

The pixel driving circuit consistent with the present disclosure may require a relatively stable process. The process is of a high stability when the semiconductor portion of the transistor uses silicon (Si) as a substrate. Thus, the pixel driving circuit consistent with the present disclosure has a promising application on the Si substrate. If the material of the semiconductor portion of the first transistor M1 is identical to the material of the semiconductor portion of the second transistor M2 (i.e., both materials use Si), then the larger the aspect ratio is, the bigger the area of the transistor will become. Hence, the aspect ratio of the second transistor M2 should not be too large, otherwise, the area of the second transistor M2 becomes bigger, leading to that the area occupied by the pixel driving circuit also becomes bigger, which is unfavorable to implement the pixel driving circuit in the display panel. In particular, in this embodiment, the condition A<B≤20A can be set. According to existing manufacturing processes, when the relationship of B=20A holds in the display panel of a high PPI (i.e., pixel per inch, e.g., 2500 PPI), the existing manufacturing process can fabricate the second transistor M2. However, if B is greater than 20 times A (i.e., B>20A), the manufacturing process will become demanding. Thus, in this embodiment, the value of 20 times A is selected as a maximum of B.

In the pixel driving circuit consistent with the present disclosure, the mirror driving module 20 is supplied with a larger input current Iₑ to obtain a smaller output current Iₒ. Since the data signal IDATA is the input current, in other words, in the pixel driving circuit consistent with the present disclosure, if the mirror driving module 20 is supplied with a larger data signal IDATA, a smaller output current Iₒ will be obtained.

In particular, for example, the pixel driving circuit may only need an output current Iₒ of 40 nA, when B is set as B=10 A, the data signal IDATA can be set to 400 nA. Due to a larger electric current of the data signal, the pixel driving circuit can be rapidly charged, thus greatly expediting the charging speed of the data signal IDATA and improving the working efficiency of the pixel driving circuit.

Moreover, the pixel driving circuit consistent with the present disclosure can lower the influence of leakage current. In particular, since the leakage current is present during transmitting the data signal IDATA, if the leakage current is 1 nA, as for the pixel driving circuit without the mirror driving module 20, in which the output current Iₒ is equal to the data signal IDATA, then the output current Iₒ will correspondingly lose by 1 nA. In contrast, with respect to the pixel driving circuit consistent with the present disclosure, owing to having the mirror driving module 20 set as B=10A, the output current is

$${I}_{o} = \frac{A}{B} * Ie = 39.9 nA .$$

That is, when the leakage current is 1 nA during transmitting the data signal IDATA, the output current only loses by 0.1 nA, thus significantly lowering the impact of the leakage current on the output current Iₒ. Because the output current associates with the driving current of the pixel driving circuit, the uniformity in the driving current of a number of pixel driving circuits can be enhanced, and the working performance of the pixel driving circuits can be improved.

Optionally, the light-emitting element D may be an organic light-emitting diode (OLED), and the second electrode of the first transistor M1 may be electrically connected to an anode of the OLED. OLED display technology has the advantages of self-luminescence, wide viewing angle, almost infinite contrast, lower power consumption, and high-speed response. The OLED generally includes an anode, an organic light-emitting portion, and a cathode, in which the organic light-emitting portion is sandwiched between the anode and the cathode. The anode and the cathode of the OLED are supplied with an appropriate voltage, electrons injected from the cathode recombines with holes from the anode in the organic light-emitting portion to produce light emission. In this embodiment, the driving current may be generated by the mirror driving module 20, and may be transmitted from the second electrode of the first transistor M1 to the anode of the OLED. The OLED may emit lights in response to the driving current.

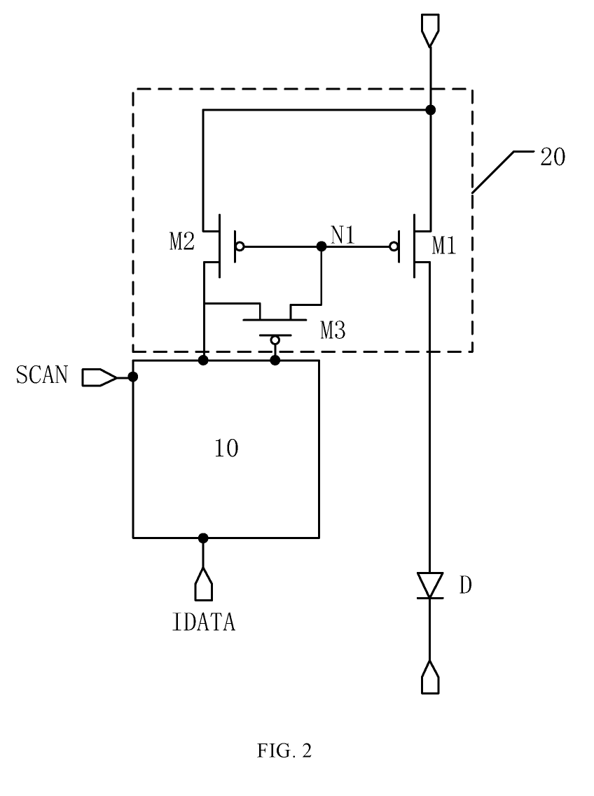

In some embodiments, referring to FIG. 2, the pixel driving circuit consistent with the present disclosure may include a data writing module 10, a mirror driving module 20, and a light-emitting element D, in which the mirror driving module 20 may include a first transistor M1 and a second transistor M2. In these embodiments, the mirror driving module 20 may also include a third transistor M3. A gate electrode of the third transistor M3 may respond to a scan signal SCAN. A first electrode of the third transistor M3 may be electrically connected to a drain electrode of the second transistor M2, and a second electrode of the third transistor M3 may be electrically connected to a first joint N1. In response to the scan signal SCAN, the data writing module 10 may transmit a data signal IDATA to the third transistor M3. After the third transistor M3 is turned on, the data signal IDATA can be transmitted through the third transistor M3 to the first joint N1.

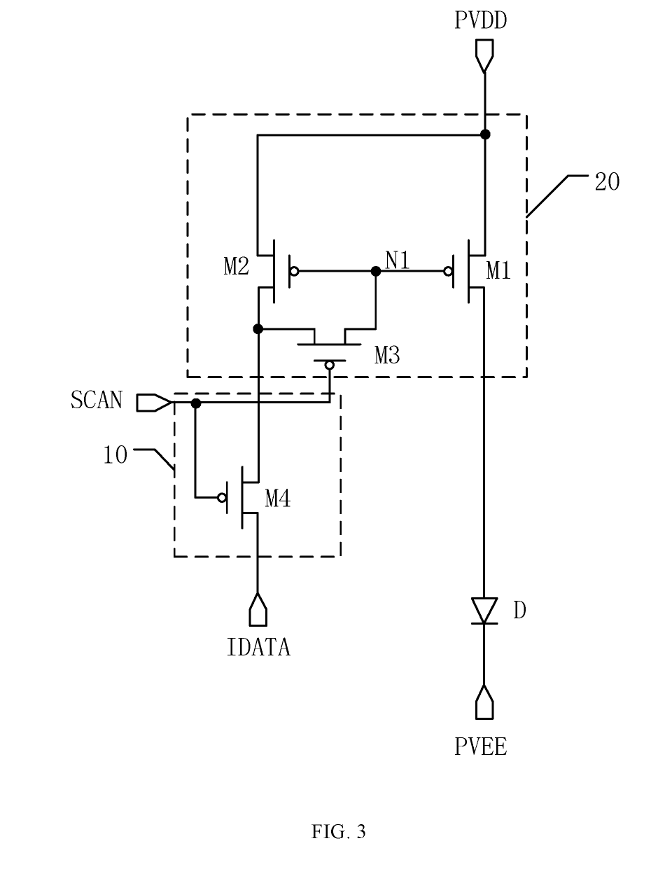

In some embodiments, referring to FIG. 3, the pixel driving circuit consistent with the present disclosure may include a data writing module 10, a mirror driving module 20, and a light-emitting element D, in which the mirror driving module 20 may include a first transistor M1 and a second transistor M2. Optionally, the mirror driving module 20 may also include a third transistor M3. In these embodiments, the data writing module 10 may include a fourth transistor M4. A gate electrode of the fourth transistor M4 may respond to a scan signal SCAN, and a first electrode of the fourth transistor M4 may receive a data signal IDATA. A second electrode of the fourth transistor M4 may be electrically connected to a second electrode of the second transistor M2. In these embodiments, the scan signal SCAN may control the fourth transistor M4 to be turned on or turned off. When the fourth transistor M4 is turned on, the data signal IDATA can be transmitted through the fourth transistor M4 to the mirror driving module 20.

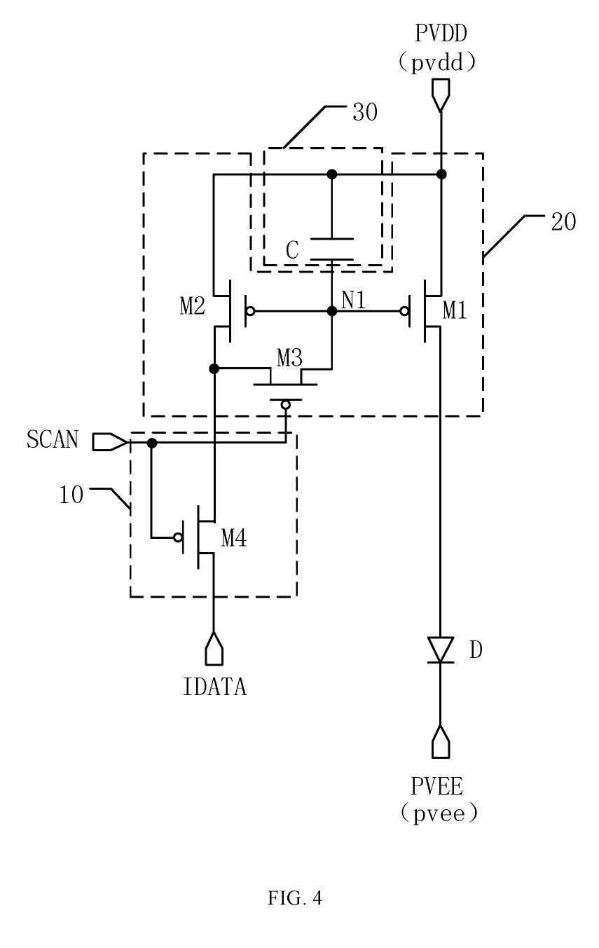

In some embodiments, referring to FIG. 4, the pixel driving circuit consistent with the present disclosure may include a data writing module 10, a mirror driving module 20, and a light-emitting element D, in which the mirror driving module 20 may include a first transistor M1 and a second transistor M2. Optionally, the mirror driving module 20 may also include a third transistor M3. Optionally, the data writing module 10 may also include a fourth transistor M4. In these embodiments, the pixel driving circuit consistent with the present disclosure may also include a maintaining module 30, which stabilizes the electric potential of a first joint N1. In these embodiments, after a data signal IDATA is transmitted to the first joint N1, the maintaining module 30 may maintain the electric potential of the first joint N1 for a certain time, thereby facilitating the pixel driving circuit to proceed with subsequent working stages.

Optionally, referring to FIG. 4, the maintaining module 30 may include a capacitive element C. A first electrode plate of the capacitive element C may be electrically connected to the first joint N1, and a second electrode plate of the capacitive element C may be electrically connected to a constant-voltage input terminal. The capacitive element C plays a role in storing an electrical signal. The capacitive element C can store brightness information, i.e., a voltage level, converted from the current data signal IDATA. The second electrode plate of the capacitive element C may be electrically connected to the constant-voltage input terminal for receiving a constant-voltage signal. The constant-voltage signal is an electrical signal having a constant voltage value.

Optionally, in the pixel driving circuit shown in FIG. 4, the first transistor M1 and the second transistor M2 receive a first voltage signal PVDD. The first voltage signal PVDD may be a constant-voltage signal.

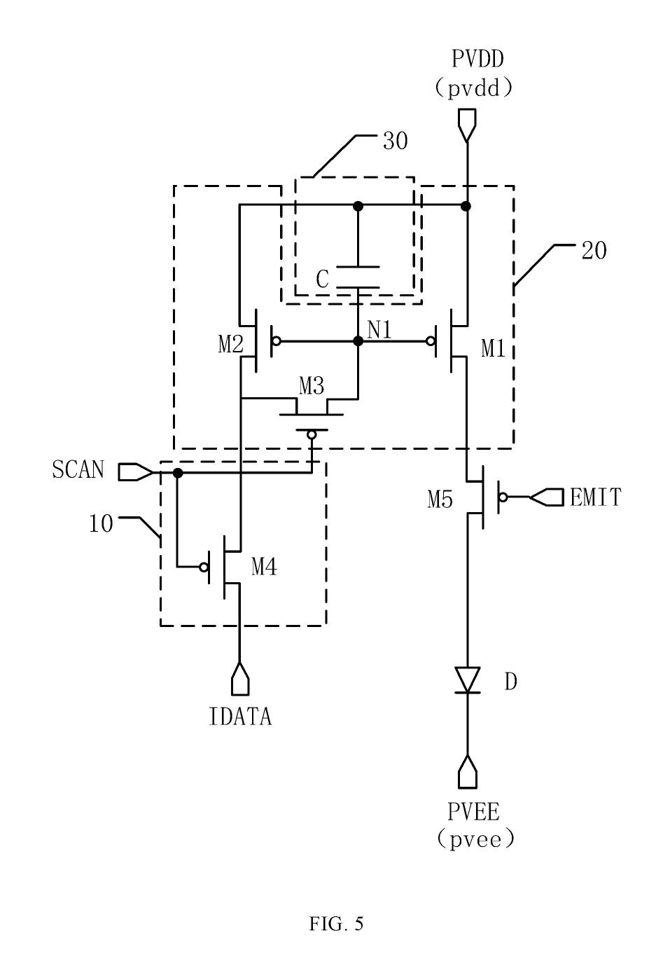

In some embodiments, referring to FIG. 5, the pixel driving circuit consistent with the present disclosure may include a data writing module 10, a mirror driving module 20 and a light-emitting element D, in which the mirror driving module 20 may include a first transistor M1 and a second transistor M2. Optionally, the mirror driving module 20 may also include a third transistor M3. Optionally, the data writing module 10 may include a fourth transistor M4. In these embodiments, the pixel driving circuit consistent with the present disclosure may also include a light-emitting control transistor M5. A gate electrode of the light-emitting control transistor M5 may receive a light-emitting control signal EMIT. A first electrode of the light-emitting control transistor M5 may be electrically connected to a second electrode of the first transistor M1, and a second electrode of the light-emitting control transistor M5 may be electrically connected to the light-emitting element D. As shown in FIG. 5, In the pixel driving circuit, the light-emitting control transistor M5 is provided. The light-emitting control signal EMIT may control the light-emitting control transistor M5 to be turned on or turned off. When the light-emitting control transistor M5 is turned on, a driving current generated by the mirror driving module 20 can be transmitted to the light-emitting element D, and the light-emitting element D can emit lights in response to the driving current.

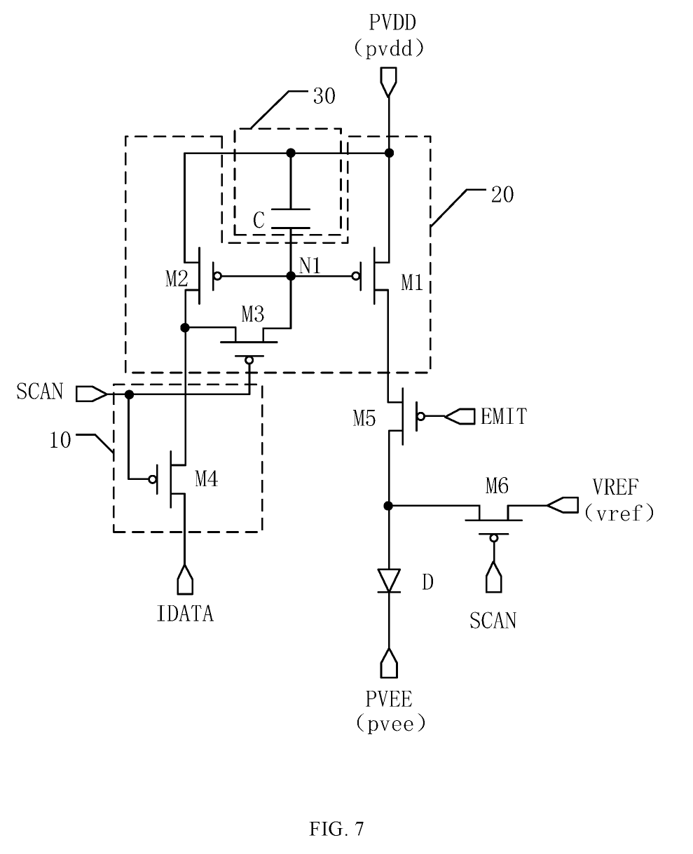

In some embodiments, referring to FIG. 7, the pixel driving circuit consistent with the present disclosure may include a data writing module 10, a mirror driving module 20, and a light-emitting element D, in which the mirror driving module may include a first transistor M1 and a second transistor M2. Optionally, the mirror driving module 20 may also include a third transistor M3. Optimally, the data writing module 10 may also a fourth transistor M4. Optionally, the pixel driving circuit may also include a light-emitting control transistor M5. As shown in FIG. 7, the pixel driving circuit also includes a reset transistor M6. A gate electrode of the reset transistor M6 may respond to a scan signal SCAN. A first electrode of the reset transistor M6 may receive a reference voltage VREF. A second electrode of the reset transistor M6 may be electrically connected to the light-emitting element D. The scan signal SCAN can control the reset transistor M6 to be turned on or turned off. When the reset transistor M6 is turned on, the reference voltage VREF can be transmitted through the reset transistor M6 to the light-emitting element D. Optionally, the light-emitting element D may be an OLED. The reference voltage VREF can be transmitted through the reset transistor M6 to an anode of the OLED for resetting the anode of the OLED.

In some embodiments, referring to FIG. 7, the pixel driving circuit may also include a high-voltage-signal input terminal pvdd and a low-voltage-signal input terminal pvee. The high-voltage-signal input terminal pvdd may be electrically connected to the first electrode of the first transistor M1, and the low-voltage-signal input terminal pvee may be electrically connected to a cathode of the OLED, in which the high-voltage-signal input terminal pvdd may supply with a first voltage signal PVDD, and the low-voltage-signal input terminal pvee may supply with a second voltage signal PVEE. Each of the first voltage signal PVDD and the second voltage signal PVEE may be a constant voltage, and the voltage of the first voltage signal PVDD may be greater than the voltage of the second voltage signal PVEE.

Optionally, referring to FIG. 7, the pixel driving circuit may also include a reference-voltage input terminal vref. The first electrode of the reset transistor M6 may be electrically connected to the reference-voltage input terminal vref for receiving the reference voltage VREF.

Each of the high-voltage-signal input terminal pvdd, the low-voltage-signal input terminal pvee, and the reference-voltage input terminal vref may supply with a constant-voltage signal. Optionally, a second electrode plate of a capacitive element C may be electrically connected to any one of the high-voltage-signal input terminal pvdd, the low-voltage-signal input terminal pvee, and the reference-voltage input terminal vref. Only one embodiment of these connections is illustrated in FIG. 7, where the second electrode plate of the capacitive element C is electrically connected to the high-voltage-signal input terminal pvdd.

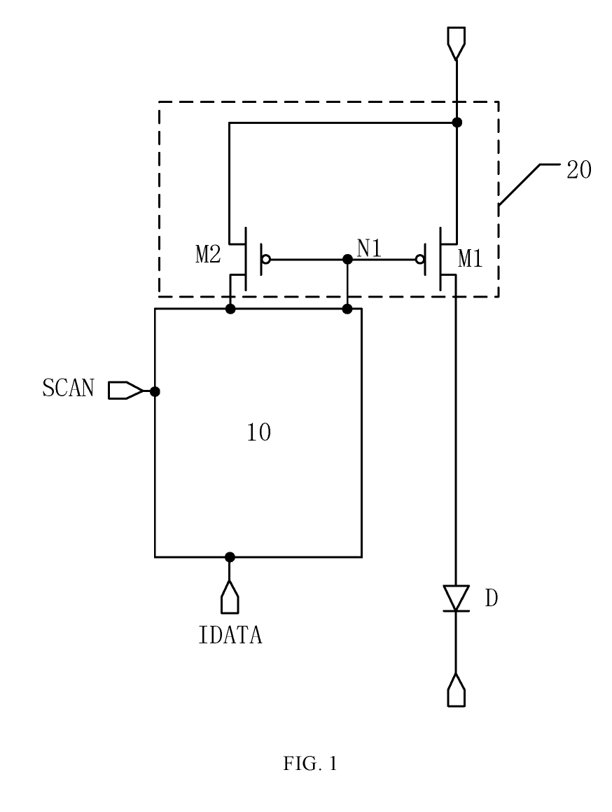

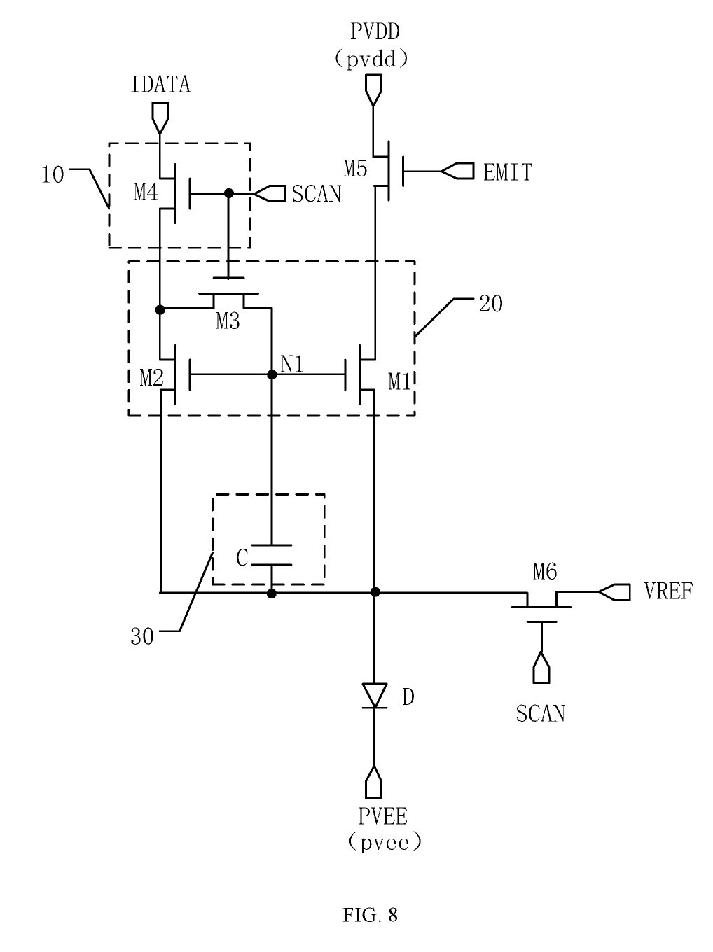

It should be noted that, in FIGS. 1 to 7, the transistors in the pixel driving circuit are illustrated using P-type transistors as an example. Optionally, referring to FIG. 8, the transistors will be illustrated using N-type transistors as an example. In these embodiments, the pixel driving circuit may include a data writing module 10, a mirror driving module 20, and a light-emitting element D, in which the mirror driving module 20 may include a first transistor M1, and a second transistor M2. A gate electrode of the first transistor M1 may be electrically connected to a gate electrode of the second transistor M2. A first electrode of the first transistor M1 and a first electrode of the second transistor M2 may be both electrically connected to the light-emitting element D. Optionally, the mirror driving module 20 may also include a third transistor M3. Optionally, the data writing module 10 may include a fourth transistor M4. As shown in FIG. 8, the pixel driving circuit may also include a light-emitting control transistor M5. A gate electrode of the light-emitting control transistor M5 may receive a light-emitting control signal EMIT. A first electrode of the light-emitting control transistor M5 may receive a first voltage signal PVDD, and a second electrode of the light-emitting control transistor M5 may be electrically connected to a second electrode of the first transistor M1.

Optionally, referring to FIG. 8, the pixel driving circuit may also include a reset transistor M6. The reset transistor M6 may respond to a scan signal SCAN. A first electrode of the reset transistor M6 may receive a reference voltage, and a second electrode of the reset transistor M6 may be electrically connected to the light-emitting element D.

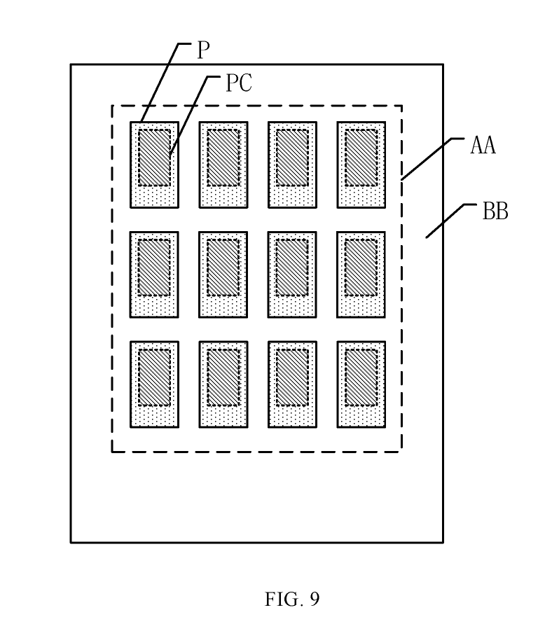

In addition to the disclosed pixel driving circuit, the present disclosure also provides a display panel. Referring to FIG. 9, the display panel consistent with the present disclosure may include a display area AA and a non-display area BB. The display area AA may include a plurality of pixels P. The pixel P may include the pixel driving circuit PC disclosed in the present disclosure. In this embodiment, the display area AA may display image information. In particular, the plurality of pixels P may implement a display function. Optionally, in the plurality of pixels P, a light-emitting element D can emit lights having different colors. For example, the plurality of pixels P may include a red pixel, a green pixel, and a blue pixel. The light-emitting elements D in the red pixel, the green pixel, and the blue pixel may emit red, green, and blue lights, respectively. Optionally, the display panel consistent with the present disclosure may be an organic light-emitting display panel, and the light-emitting element D may be an OLED.

When the display panel consistent with the present disclosure is operating, the electric current of the data signal of the pixel P may be set relatively large. Since the electric current of the data signal is relatively large, the pixel driving circuit PC can be rapidly charged, which significantly expedites the charging speed of the data signal and improves the working efficiency of the pixel driving circuit. If the display panel has a relatively high PPI, within one frame, the number of pixels P that need to be refreshed will be relatively high, which leads to a reduction in working time for each pixel P. Because, in the display panel consistent with the present disclosure, the working efficiency of the pixel driving circuit is relatively high, requirements by the high-PPI display panel can be satisfied.

Moreover, the pixel driving circuit consistent with the present disclosure can mitigate the influence of the leakage current. Since the display area AA includes the plurality of pixels P and the distances between the plurality of pixels P and a data signal terminal (not shown) are different, the data signal IDATA of the data signal terminal is transmitted to different pixels P at varied distances and the amount of the leakage current during transmitting the data signal IDATA is varied. The display panel consistent with the present disclosure can significantly lower the influence of the leakage current on the plurality of pixels P, thereby improving the uniformity in the driving currents of the driving circuits PC of the plurality of pixels P (i.e., improving the uniformity of the plurality of pixels P), and enhancing the display quality.

The display panel consistent with the present disclosure may have the beneficial effects of the pixel driving circuit consistent with the present disclosure. The details can be referred to the specific description of the pixel driving circuit in each of the foregoing embodiments, which will not be repeated herein.

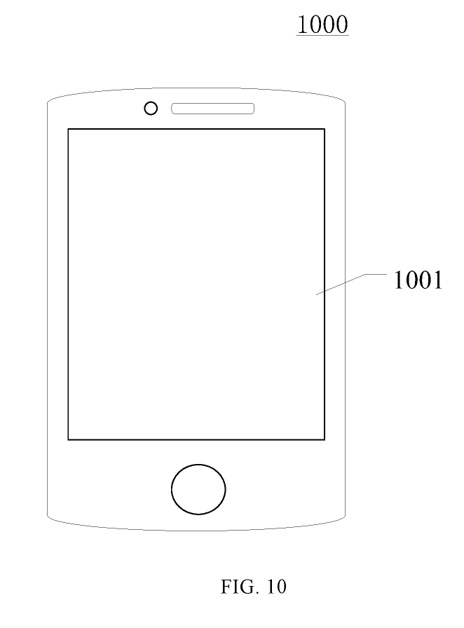

In addition to the disclosed pixel driving circuit and display panel, the present disclosure also provides a display device including the disclosed display panel. Referring to FIG. 10, the display device 1000 shown in FIG. 10 includes the display panel 1001 disclosed in any one of the foregoing embodiments. The embodiment shown in FIG. 10 only takes a mobile phone as an example to illustrate the display device 1000. It can be understood that the display device consistent with the present disclosure may be a display device having the display function, such as a computer, a television, an in-vehicle display device, etc., which is not limited herein. The display device consistent with the present disclosure may have the beneficial effects of the display panel consistent with the present disclosure. The details can be referred to the specific description of the display panel in each of the foregoing embodiments, which will not be repeated herein.

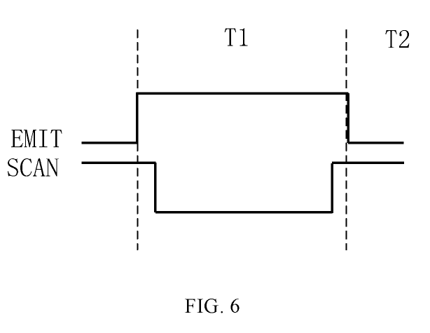

In addition to the disclosed pixel driving circuit, display panel and display device, the present disclosure also provides a driving method of a pixel driving circuit. Referring to FIG. 5 and FIG. 6, the pixel driving circuit may include a data writing module 10, a mirror driving module 20 and a light-emitting element D. The mirror driving module 20 may include a first transistor M1 and a second transistor M2. A gate electrode of the first transistor M1 and a gate electrode of the second transistor M2 may be both electrically connected to a first joint N1. A first electrode of the first transistor M1 may be electrically connected to a first electrode of the second transistor M2. A threshold voltage of the first transistor M1 may be equal to a threshold voltage of the second transistor M2. An aspect ratio of the first transistor M1 may be A and an aspect ratio of the second transistor M2 may be B, and A<B.

The driving method may include a data writing stage T1 and a light-emitting stage T2. In the data writing stage T1, the data writing module 10 is inputted with the scan signal SCAN. The data writing module 10 in response to the scan signal SCAN may transmit the data signal IDATA to the first joint N1. In the light-emitting stage T2, the mirror driving module 20 may receive the data signal IDATA, and generate a driving current for driving the light-emitting element D to emit lights.

In the driving method consistent with the present disclosure, the mirror driving module 20 may be supplied with a larger data signal IDATA to obtain a smaller output current. Since the electric current of the data signal is relatively large, the pixel driving circuit can be rapidly charged, which can significantly expedite the charging speed of the data signal IDATA and improve the working efficiency of the pixel driving circuit. Moreover, the driving method consistent with the present disclosure can lower the impact of the leakage current, and can enhance the working performance of the pixel driving circuit.

Optionally, referring to FIG. 5 and FIG. 6, the mirror driving module 20 may also include a third transistor M3. A gate electrode of the third transistor M3 may respond to the scan signal SCAN. A first electrode of the third transistor M3 may be electrically connected to a drain electrode of the second transistor M2. A second electrode of the third transistor M3 may be electrically connected to the first joint N1. The data writing module 10 may include a fourth transistor M4. The gate electrode of the fourth transistor M4 may respond to the scan signal SCAN. A first electrode of the fourth transistor M4 may receive the data signal IDATA. A second electrode of the fourth transistor M4 may be electrically connected to a second electrode of the second transistor M2. The pixel driving circuit may also include a light-emitting control transistor M5. The gate electrode of the light-emitting control transistor M5 may receive a light-emitting control signal EMIT. A first electrode of the light-emitting control transistor M5 may be electrically connected to the second electrode of the first transistor M1. A second electrode of the light-emitting control transistor M5 may be electrically connected to the light-emitting element D. Optionally, a first electrode plate of a capacitive element C may be electrically connected to the first joint N1, and a second electrode plate of the capacitive element C may be electrically connected to a high-voltage-signal input terminal pvdd, for receiving a first voltage signal PVDD.

Optionally, in the data writing stage T1, the light-emitting control signal EMIT may be a first voltage, and the scan signal SCAN may be a second voltage. In the light-emitting stage T2, the light-emitting control signal EMIT may be the second voltage, and the scan signal SCAN may be the first voltage.

FIG. 5 only illustrates the case where the transistors in the pixel driving circuit are the P-type transistors. FIG. 6 only illustrates the first voltage as a high voltage and the second voltage as a low voltage.

In particular, in the data writing stage T1, the third transistor M3 and the light-emitting control transistor M4 may be turned on under the control of the low-voltage scan signal. The data signal IDATA may be transmitted to the first joint N1. When the voltage V_{N1} of the first joint N1 satisfies IDATA=K*(V_{N1}−V_{PVDD}−Vₜₕ)², the voltage V_{N1} of the first joint N1 may be maintained and remain as V_{N1}, where Vₜₕ is the threshold voltage of the first transistor M1, and V_{PVDD} is the voltage of the first voltage signal PVDD received by the first electrode of the first transistor M1.

In the light-emitting stage T2, the third transistor M3 and the light-emitting control transistor M5 may be turned off under the control of the high-voltage scan signal SCAN, while the light-emitting control transistor M5 may be turned on under the control of the low-voltage light-emitting control signal EMIT. After the data writing stage T1 is completed, the voltage V_{N1} of the first joint N1 may be maintained stable by the capacitive element C, and the first transistor M1 may be turned on under the control of the voltage V_{N1} of the first joint N1. The first voltage signal PVDD may be transmitted to the mirror driving module 20, and the mirror driving module 20 may generate the driving current. The generated driving current may be transmitted through the light-emitting control transistor M5 to the light-emitting element D, and the light-emitting element D may emit lights in response to the driving current.

Although some specific embodiments of the present disclosure have been described in detail by certain examples, those skilled in the art should understand that the above examples are only for illustrative purposes, and are not intended to limit the scope of the present disclosure. Those skilled in the art should also understand that the above embodiments may be modified without departing from the scope and spirit of the present disclosure. The scope of the present disclosure is defined by the appended claims.

What is claimed is:

1. A pixel driving circuit, comprising:
a data writing module, in response to a scan signal, for transmitting a data signal;
a mirror driving module for receiving the data signal and generating a driving current, including a first transistor and a second transistor; and
a light-emitting element, in response to the driving current, for emitting lights,
wherein:
a gate electrode of the first transistor and a gate electrode of the second transistor are both electrically connected to a first joint;
a first electrode of the first transistor is electrically connected to a first electrode of the second transistor;
a threshold voltage of the first transistor is equal to a threshold voltage of the second transistor; and
an aspect ratio of the first transistor is A and an aspect ratio of the second transistor is B, and A<B≤20A.

2. The pixel driving circuit according to claim 1, wherein:
the light-emitting element is an organic light-emitting diode; and
a second electrode of the first transistor is electrically connected to an anode of the organic light emitting diode.

3. The pixel driving circuit according to claim 1, wherein:
the mirror driving module further includes a third transistor;
a gate electrode of the third transistor responds to the scan signal;
a first electrode of the third transistor is electrically connected to a drain electrode of the second transistor; and
a second electrode of the third transistor is electrically connected to the first joint.

4. The pixel driving circuit according to claim 1, wherein:
the data writing module includes a fourth transistor;
a gate electrode of the fourth transistor responds to the scan signal;
a first electrode of the fourth transistor receives the data signal; and
a second electrode of the fourth transistor is electrically connected to the second electrode of the second transistor.

5. The pixel driving circuit according to claim 1, further including:
a maintaining module for stabilizing an electrical potential of the first joint.

6. The pixel driving circuit according to claim 5, wherein:
the maintaining module includes a capacitive element;
a first electrode plate of the capacitive element is electrically connected to the first joint; and
a second electrode plate of the capacitive element is electrically connected to a constant-voltage input terminal.

7. The pixel driving circuit according to claim 1, wherein:
the pixel driving circuit further includes a light-emitting-control transistor;
a gate electrode of the light-emitting-control transistor receives a light-emitting-control signal;
a first electrode of the light-emitting-control transistor is electrically connected to the second electrode of the first transistor; and
a second electrode of the light-emitting-control transistor is electrically connected to the light-emitting element.

8. The pixel driving circuit according to claim 1, wherein:
the pixel driving circuit further includes a light-emitting-control transistor;
a gate electrode of the light-emitting-control transistor receives a light-emitting-control signal;
a first electrode of the light-emitting-control transistor receives a first voltage signal; and
a second electrode of the light-emitting-control transistor is electrically connected to the second electrode of the first transistor.

9. The pixel driving circuit according to claim 6, wherein:
the pixel driving circuit further includes a reset transistor;
a gate electrode of the reset transistor responds to the scan signal;
a first electrode of the reset transistor receives a reference voltage; and
a second electrode of the reset transistor is electrically connected to the light-emitting element.

10. The pixel driving circuit according to claim 6, wherein:
the pixel driving circuit further includes a high-voltage-signal-input terminal and a low-voltage-signal-input terminal;
the high-voltage-signal-input terminal is electrically connected to the first electrode of the transistor; and
the low-voltage-signal-input terminal is electrically connected to a cathode of the organic light-emitting diode.

11. The pixel driving circuit according to claim 10, wherein:
the constant-voltage input terminal is either the high-voltage-signal-input terminal or the low-voltage-signal-input terminal.

12. The pixel driving circuit according to claim 9, wherein:
the pixel driving circuit further includes a reference-voltage input terminal;
the first electrode of the reset transistor is electrically connected to the reference-voltage input terminal for receiving the reference voltage; and
the constant-voltage input terminal is the reference-voltage input terminal.

13. A display panel, comprising:
a non-display area;
a display area including a plurality of pixels; and
a pixel driving circuit for driving the plurality of pixels, wherein the pixel driving circuit comprises:
a data writing module, in response to a scan signal, for transmitting a data signal;
a mirror driving module for receiving the data signal and generating a driving current, including a first transistor and a second transistor; and
a light-emitting element, in response to the driving current, for emitting lights,
wherein:
a gate electrode of the first transistor and a gate electrode of the second transistor are both electrically connected to a first joint;
a first electrode of the first transistor is electrically connected to a first electrode of the second transistor;
a threshold voltage of the first transistor is equal to a threshold voltage of the second transistor; and
an aspect ratio of the first transistor is A and an aspect ratio of the second transistor is B, and A<B≤20A.

14. A display device, comprising a display panel according to claim 13.

15. A driving method of a pixel driving circuit, wherein:
the pixel driving circuit includes a data writing module, a mirror driving module and a light-emitting element; the mirror driving module includes a first transistor and a second transistor; a gate electrode of the first transistor and a gate electrode of the second transistor are both electrically connected to a first joint; a first electrode of the first transistor is electrically connected to a first electrode of the second transistor; a threshold voltage of the first transistor is equal to a threshold voltage of the second transistor; and an aspect ratio of the first transistor is A and an aspect ratio of the second transistor is B, and A<B; and the driving method includes:
providing a data writing stage and a light-emitting stage;
in the data writing stage, inputting a scan signal into the data writing module, wherein the data writing module in response to the scan signal transmits a data signal to the first joint; and
in the light-emitting stage, receiving, by the mirror driving module, the data signal and generating a driving current to drive the light-emitting element for emitting lights.

16. The driving method according to claim 15, wherein:
the mirror driving module further includes a third transistor;
a gate electrode of the third transistor responds to the scan signal;
a first electrode of the third transistor is electrically connected to a drain electrode of the second transistor;
a second electrode of the third transistor is electrically connected to the first joint;
the data writing module includes a fourth transistor;
a gate electrode of the fourth transistor responds to the scan signal;
a first electrode of the fourth transistor receives the data signal;
a second electrode of the fourth transistor is electrically connected to the second electrode of the second transistor;
the pixel driving circuit further includes a light-emitting-control transistor;
a gate electrode of the light-emitting-control transistor receives a light-emitting-control signal;
a first electrode of the light-emitting-control transistor is electrically connected to the second electrode of the first transistor; and
a second electrode of the light-emitting-control transistor is electrically connected to the light-emitting element.

17. The driving method according to claim 16, wherein:
in the data writing stage, the light-emitting-control signal is a first voltage, and the scan signal is a second voltage; and
in the light-emitting stage, the light-emitting-control signal is the second voltage, and the scan signal is the first voltage.
